(19) United States
(12) Patent Application Publication
(10) Pub. No.: US 2026/0304740 A1
(43) Pub. Date: Oct. 1, 2026

(54) MEMORY DEVICE INCLUDING CHANNEL STRUCTURE

(71) Applicant: SK hynix Inc., Icheon-si (KR)

(72) Inventor: Heon Yong CHANG, Icheon-si (KR)

(21) Appl. No.: 19/292,625

(22) Filed: Aug. 6, 2025

(30) Foreign Application Priority Data
Apr. 1, 2025 (KR) 10-2025-0042013

(51) Int. Cl. H10B 12/00; G11C 5/06; H10D 1/68

(52) U.S. Cl. CPC H10B 12/312; G11C 5/063; H10B 12/0335; H10B 12/482; H10D 1/716

(57) ABSTRACT

A memory device may include a channel structure including a first end and a second end that is opposite to the first end in a vertical direction; a data storage pattern connected to the first end of the channel structure; a bit line contacting the second end of the channel structure; a bonding insulating layer disposed over the bit line; a first substrate disposed over the bonding insulating layer, and including a first surface that faces the bit line and a second surface that is opposite to the first surface in the vertical direction; and a first transistor disposed on the second surface of the first substrate.

### CROSS-REFERENCE TO RELATED APPLICATION

The present application claims priority under 35 U.S.C. § 119(a) to Korean Patent Application No. 10-2025-0042013 filed on Apr. 1, 2025, which is incorporated herein by reference in its entirety.

### BACKGROUND

### 1. Technical Field

Embodiments of the present disclosure relate to a memory device.

### 2. Related Art

Memory devices are attracting attention as an important element in the electronics industry due to characteristics such as miniaturization, multifunctionality and/or low manufacturing cost. As the electronics industry has developed rapidly, memory devices are becoming increasingly highly integrated.

In two-dimensional or planar semiconductor memory devices, the degree of integration is mainly determined by the area occupied by a unit memory cell, and is thus greatly affected by the level of fine pattern formation technology. However, because ultra-expensive equipment is required to refine patterns, the degree of integration of two-dimensional semiconductor memory devices is reaching its limit. Accordingly, semiconductor memory devices including vertical channel transistors in which channels extend in a vertical direction are being proposed.

### SUMMARY

Embodiments of the present disclosure are directed to providing a memory device capable of simplifying a process of forming wirings.

Objects of embodiments of the disclosure are not limited to those set forth herein, and other unmentioned objects would be apparent to one of ordinary skill in the art from the following description.

In an embodiment, a memory device may include: a channel structure including a first end and a second end that is opposite to the first end in a vertical direction; a data storage pattern connected to the first end of the channel structure; a bit line contacting the second end of the channel structure; a bonding insulating layer disposed over the bit line; a first substrate disposed over the bonding insulating layer, and including a first surface that faces the bit line and a second surface that is opposite to the first surface in the vertical direction; and a first transistor disposed on the second surface of the first substrate.

In an embodiment, a memory device may include: a first semiconductor structure including a channel structure, a bit line that contacts the upper surface of the channel structure and a first bonding insulating layer over the bit line; a second semiconductor structure including a second bonding insulating layer that is bonded to the first bonding insulating layer, a first substrate that is disposed over the second bonding insulating layer and a first transistor that is disposed on the first substrate; and a plurality of contact plugs including a first contact plug, a second contact plug and a third contact plug that are spaced apart from each other, that connect the first semiconductor structure and the second semiconductor structure by penetrating through the first substrate, the first bonding insulating layer and the second bonding insulating layer.

In an embodiment, a memory device may include: a channel structure including a first end and a second end that is located opposite to the first end in a vertical direction; a data storage pattern connected to the first end of the channel structure; a bit line contacting the second end of the channel structure; a bonding insulating layer located over the bit line; a first substrate located over the bonding insulating layer; a plurality of wirings located over the first substrate; and a plurality of contact plugs directly connected to the plurality of wirings, respectively, and penetrating through the bonding insulating layer and the first substrate.

According to embodiments of the present disclosure, it is possible to provide a memory device capable of simplifying a process of forming wirings.

The effects of the disclosure are not limited to the foregoing objects, and other effects will be apparent to one of ordinary skill in the art from the following detailed description.

### BRIEF DESCRIPTION OF THE DRAWINGS

The disclosure will be more fully understood from the following detailed description and the accompanying drawings, which are provided for illustration only and are not intended to limit the disclosure.

FIG. 1 is a view illustrating an example of a cross-sectional structure of a memory device according to embodiments of the present disclosure.

FIG. 2 to FIG. 11 are views illustrating an example of a method of manufacturing a memory device according to embodiments of the present disclosure.

### DETAILED DESCRIPTION

Hereinafter, embodiments of the present disclosure will be described in detail with reference to the accompanying drawings. In the following description, the same elements will be designated by the same reference numerals although they are shown in different drawings. Further, in the following description of the present disclosure, a detailed description of known functions and configurations incorporated herein will be omitted when it may make the subject matter of the present disclosure more unclear. It is to be noticed that the terms “comprising,” “having,” “including” and so on, used in the description and claims, should not be interpreted as being restricted to the means listed thereafter unless specifically stated otherwise. Where an indefinite or definite article is used when referring to a singular noun, e.g., “a,” “an” and “the,” this may include a plural of that noun unless specifically stated otherwise.

Also, in describing the components of the disclosure, there may be terms used like first, second, A, B, (a), and (b). These are solely for the purpose of differentiating one component from another component but do not limit the substances, order, sequence or number of the components.

When it is mentioned that a first element “is connected or coupled to,” “contacts or overlaps,” etc. a second element, it should be interpreted that not only can the first element “be directly connected or coupled to” or “directly contact or overlap” the second element, but a third element can also be “interposed” between the first and second elements or the first and second elements can “be connected or coupled to,” “contact or overlap,” etc. each other via a fourth element. Here, another component may be included in at least one of the at least two components that are “connected,” “coupled” or “linked” with each other.

In descriptions for time flow relationships of components, in an operating method or in a fabricating method, when pre and post relationships in terms of time or pre and post relationships in terms of flow are described, such as for example, by “after,” “following,” “next” or “before,” non-continuous cases may be included unless “immediately” or “directly” is used.

Where a numerical value for a component or its corresponding information (e.g., a level, etc.) is mentioned, even though there is no separate explicit description, the numerical value or its corresponding information can be interpreted as including an error range that may be caused by various factors (for example, a process variable, an internal or external shock, noise, etc.).

In the accompanying drawings, two directions that are parallel to the upper surface of a first substrate are defined as a first direction FD and a second direction SD, respectively, and a direction that vertically protrudes from the upper surface of the first substrate is defined as a third direction VD. The first direction FD and the second direction SD may be substantially perpendicular to each other. The third direction VD is a direction that is perpendicular to the first direction FD and the second direction SD. In the following description, the term ‘vertical’ or ‘vertical direction’ will be used as substantially the same meaning as the third direction VD. In the drawings, a direction indicated by an arrow and a direction opposite thereto represent the same direction.

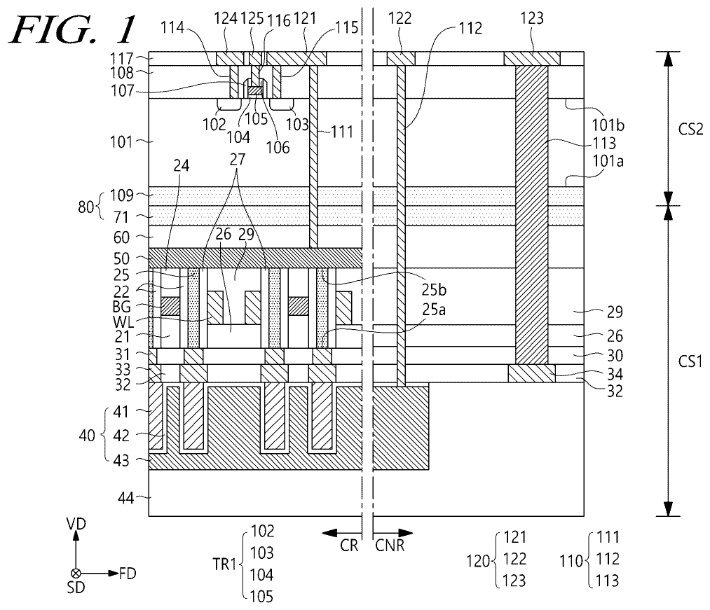

FIG. 1 is a view illustrating an example of a cross-sectional structure of a memory device according to embodiments of the present disclosure.

Referring to FIG. 1, a memory device according to the embodiments of the present disclosure may include a first semiconductor structure CS1, a second semiconductor structure CS2, and contact plugs 110. The first semiconductor structure CS1 may include memory cells. The second semiconductor structure CS2 may include peripheral circuits that are connected to the memory cells.

The first semiconductor structure CS1 may include a first insulating pattern 21, a first gate insulating layer 22, a back gate electrode BG, a second insulating pattern 24, a channel structure 25, a third insulating pattern 26, a second gate insulating layer 27, a word line WL, a fourth insulating pattern 29, a first interlayer insulating layer 30, a storage node contact 31, a second interlayer insulating layer 32, a landing pad 33, a conductive pad 34, a data storage pattern 40, a first insulating layer 44, a bit line 50, a second insulating layer 60, and a first bonding insulating layer 71.

The second semiconductor structure CS2 may include a first substrate 101, a first transistor TR1, a gate capping layer 106, a spacer 107, a third insulating layer 108, a second bonding insulating layer 109, the contact plugs 110, a source contact 114, a drain contact 115, a gate contact 116, a fourth insulating layer 117, wirings 120, a source wiring 124, and a gate wiring 125. The contact plugs 110 may include a first contact plug 111, a second contact plug 112 and a third contact plug 113.

The data storage pattern 40 may include a first electrode 41, a dielectric layer 42 and a second electrode 43. The first transistor TR1 may include a source region 102, a drain region 103, a third gate insulating layer 104, and a first gate electrode 105. The wirings 120 may include a first wiring 121, a second wiring 122 and a third wiring 123.

The first semiconductor structure CS1 may include a cell region CR and a connection region CNR. The cell region CR may mean a region where memory cells are disposed. The connection region CNR may mean a region where various contacts for connecting the memory cells to the peripheral circuits are disposed. Alternatively, the connection region CNR may be a region where electrodes for connecting one semiconductor chip to another semiconductor chip are disposed.

The first gate insulating layer 22 may be disposed on both side surfaces of the first insulating pattern 21, the back gate electrode BG and the second insulating pattern 24. The first gate insulating layer 22 may be disposed on the side surfaces of the first insulating pattern 21, the back gate electrode BG and the second insulating pattern 24. The first gate insulating layer 22 may be disposed on both side surfaces of the back gate electrode BG. The first gate insulating layer 22 may electrically insulate the back gate electrode BG and the channel structure 25 from each other.

The channel structure 25 may be disposed on the side surface of the first gate insulating layer 22. The channel structure 25 may include a first end 25a and a second end 25b that are located opposite each other in the vertical direction. The first end 25a may mean the lower surface of the channel structure 25. The second end 25b may mean the upper surface of the channel structure 25. Hereinafter, the first end 25a of the channel structure 25 may be referred to as the lower surface of the channel structure 25. Similarly, the second end 25b of the channel structure 25 may be referred to as the upper surface of the channel structure 25.

The channel structure 25 may include a source region, a channel region and a drain region. In an embodiment, the channel region may be located between the source region and the drain region in the vertical direction. The source region may be disposed in a region that neighbors or is proximate to the second end 25b of the channel structure 25. The drain region may be disposed in a region that neighbors or is proximate to the first end 25a of the channel structure 25. Alternatively, the locations of the source region and the drain region may be reversed. The channel structure 25 may be located between one word line WL and one back gate electrode BG.

The third insulating pattern 26, the second gate insulating layer 27 and the fourth insulating pattern 29 may be disposed on the side surface of the channel structure 25. The second gate insulating layer 27 may be disposed between the word line WL and the channel structure 25. The second gate insulating layer 27 may electrically insulate the word line WL and the channel structure 25 from each other. In an embodiment, the first gate insulating layer 22 and the second gate insulating layer 27 may contact at least portions of the side surfaces of the channel structure 25.

The first interlayer insulating layer 30 may be disposed under the channel structure 25, the first gate insulating layer 22, the second gate insulating layer 27, the first insulating pattern 21 and the third insulating pattern 26. The storage node contact 31 may be directly connected to the channel structure 25 by penetrating through the first interlayer insulating layer 30. For example, one surface (e.g., the upper surface) of the storage node contact 31 may contact the first end 25a of the channel structure 25.

The second interlayer insulating layer 32 may be disposed under the first interlayer insulating layer 30. The landing pad 33 may be connected to the storage node contact 31 by penetrating through the second interlayer insulating layer 32. In the connection region CNR, the conductive pad 34 may be disposed in the second interlayer insulating layer 32. The conductive pad 34 may be disposed at the same layer as the landing pad 33. The conductive pad 34 may contact one surface (e.g., the lower surface) of the first interlayer insulating layer 30 by penetrating through the second interlayer insulating layer 32.

The data storage pattern 40 may be disposed under the landing pad 33 and the second interlayer insulating layer 32. In an embodiment, the data storage pattern 40 may be a capacitor. The data storage pattern 40 may be electrically connected to the first end 25a of the channel structure 25 through the storage node contact 31 and the landing pad 33.

The first electrode 41 of the data storage pattern 40 may contact one surface (e.g., the lower surface) of the landing pad 33. The first electrode 41 is illustrated as having a pillar shape, but the shape of the first electrode 41 is not limited thereto. The dielectric layer 42 may be disposed to cover the surface of the first electrode 41. The dielectric layer 42 is illustrated as contacting one surface (e.g., the lower surface) of the second interlayer insulating layer 32, but embodiments are not necessarily limited thereto. For example, an etch stop layer may be further disposed between the dielectric layer 42 and the second interlayer insulating layer 32. The second electrode 43 may surround the first electrode 41 and the dielectric layer 42. At least portions of the dielectric layer 42 and the second electrode 43 may also be disposed in the connection region CNR. The first insulating layer 44 may be disposed to cover the second electrode 43.

The bit line 50 may be connected to the second end 25b of the channel structure 25. For example, one surface (e.g., the lower surface) of the bit line 50 may contact the second end 25b of the channel structure 25. The bit line 50 may extend in the first direction FD.

The second insulating layer 60 may be disposed to cover the bit line 50. The first bonding insulating layer 71 may be disposed on the second insulating layer 60. One surface (e.g., the upper surface) of the first bonding insulating layer 71 may serve as a surface (e.g., the upper surface) of the first semiconductor structure CS1.

The second semiconductor structure CS2 is bonded onto the first semiconductor structure CS1. One surface (e.g., the lower surface) of the second semiconductor structure CS2 may contact a surface (e.g., the upper surface) of the first bonding insulating layer 71.

The first substrate 101 of the second semiconductor structure CS2 may include a first surface 101a and a second surface 101b. The second surface 101b may be located opposite to the first surface 101a in the vertical direction. The first surface 101a is a surface that faces the bit line 50, and may mean the lower surface of the first substrate 101. The second surface 101b may mean the upper surface of the first substrate 101. In an embodiment, the first surface 101a of the first substrate 101 may contact the second bonding insulating layer 109. Hereinafter, the first surface 101a of the first substrate 101 may be referred to as the lower surface of the first substrate 101. Similarly, the second surface 101b of the first substrate 101 may be referred to as the upper surface of the first substrate 101.

The first transistor TR1 may be disposed on the second surface 101b of the first substrate 101. The first transistor TR1 may be a transistor that transmits various voltages or signals to a memory cell. Although FIG. 1 illustrates only one first transistor TR1, first transistor TR1 may mean any transistor included in a peripheral circuit, such as a sensing transistor, a transmission transistor or a driving transistor. The first transistor TR1 may be located in an area bounded by the wirings 120 and the first surface 101a of the first substrate 101.

The source region 102 and the drain region 103 of the first transistor TR1 may be disposed in the first substrate 101. Between the source region 102 and the drain region 103, the third gate insulating layer 104 may be disposed on the first substrate 101. The first gate electrode 105 and the gate capping layer 106 may be sequentially disposed on the third gate insulating layer 104. The spacer 107 may be disposed on the side surfaces of the third gate insulating layer 104, the first gate electrode 105 and the gate capping layer 106.

The third gate insulating layer 104, the first gate electrode 105 and the gate capping layer 106 may be disposed on the second surface 101b of the first substrate 101. The third gate insulating layer 104, the first gate electrode 105 and the gate capping layer 106 may be located opposite to the second bonding insulating layer 109 when viewed on the basis of the first substrate 101.

The third insulating layer 108 may be disposed on the first substrate 101 and the first transistor TR1. The source contact 114 and the drain contact 115 may be connected to the source region 102 and the drain region 103, respectively, by penetrating through the third insulating layer 108. The gate contact 116 may contact the upper surface of the first gate electrode 105 by penetrating through the third insulating layer 108 and the gate capping layer 106.

The fourth insulating layer 117 may be disposed on the third insulating layer 108, the source contact 114, the drain contact 115 and the gate contact 116. The wirings 120, the source wiring 124 and the gate wiring 125 may penetrate through the fourth insulating layer 117. The wirings 120 may be disposed in the same layer to be spaced apart from each other. For example, the first wiring 121, the second wiring 122, the third wiring 123, the source wiring 124 and the gate wiring 125 may be spaced apart from each other in the first direction FD. The first wiring 121 may be connected to the drain contact 115. The first wiring 121 may also be referred to as a drain wiring. The source wiring 124 may be connected to the source contact 114. The gate wiring 125 may be connected to the gate contact 116.

The first contact plug 111 may connect the first semiconductor structure CS1 and the second semiconductor structure CS2 by penetrating through the third insulating layer 108, the first substrate 101, a bonding insulating layer 80, which includes the first bonding insulating layer 71 and the second bonding insulating layer 109, and the second insulating layer 60. For example, the first contact plug 111 may connect the first wiring 121 and the bit line 50 to each other. For example, one end of the first contact plug 111 may contact one surface (e.g., the lower surface) of the first wiring 121, and the other end of the first contact plug 111 may contact the other surface (e.g., the upper surface) of the bit line 50. The first transistor TR1 may be connected to the bit line 50 through the drain contact 115, the first wiring 121 and the first contact plug 111.

The second contact plug 112 may connect the first semiconductor structure CS1 and the second semiconductor structure CS2 by penetrating through the third insulating layer 108, the first substrate 101, the bonding insulating layer 80, the second insulating layer 60, the fourth insulating pattern 29, the third insulating pattern 26, the first interlayer insulating layer 30, the second interlayer insulating layer 32 and the dielectric layer 42. For example, the second contact plug 112 may connect the second wiring 122 and the data storage pattern 40 to each other. For example, one end of the second contact plug 112 may contact one surface (e.g., the lower surface) of the second wiring 122, and the other end of the second contact plug 112 may contact one surface (e.g., the upper surface) of the second electrode 43 of the data storage pattern 40.

The third contact plug 113 may connect the first semiconductor structure CS1 and the second semiconductor structure CS2 by penetrating through the third insulating layer 108, the first substrate 101, the bonding insulating layer 80, the second insulating layer 60, the fourth insulating pattern 29, the third insulating pattern 26 and the first interlayer insulating layer 30. For example, the third contact plug 113 may connect the third wiring 123 and the conductive pad 34 to each other. For example, one end of the third contact plug 113 may contact one surface (e.g., the lower surface) of the third wiring 123, and the other end of the third contact plug 113 may contact one surface (e.g., the upper surface) of the conductive pad 34. The third contact plug 113 may also be referred to as a through electrode. In some embodiments, contacts that penetrate through the first insulating layer 44 may be additionally disposed under the conductive pad 34. In an embodiment, the third contact plug 113 may serve to electrically connect the semiconductor device to the outside of the semiconductor device.

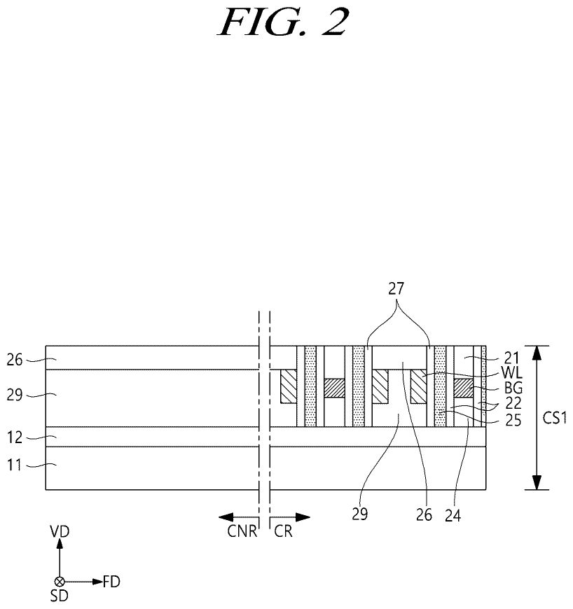

FIG. 2 to FIG. 11 are views illustrating an example of a method of manufacturing a memory device according to embodiments of the present disclosure.

Referring to FIG. 2, a first semiconductor structure CS1 that includes a second substrate 11 is prepared. The second substrate 11 may include a semiconductor substrate such as a silicon wafer or a silicon-on-insulator (SOI) wafer. The second substrate 11 may include a III-V group semiconductor substrate, for example, a compound semiconductor substrate such as GaAs. The second substrate 11 may include monocrystalline silicon, polysilicon, amorphous silicon, monocrystalline silicon germanium, polycrystalline silicon germanium, carbon-doped silicon, or a combination thereof.

A fifth insulating layer 12 is formed on the second substrate 11. In a cell region CR, a first insulating pattern 21, a back gate electrode BG and a second insulating pattern 24 may be formed on the fifth insulating layer 12. A first gate insulating layer 22 may be disposed on both side surfaces of each of the first insulating pattern 21, the back gate electrode BG and the second insulating pattern 24.

The fifth insulating layer 12, the first insulating pattern 21, the second insulating pattern 24 and the first gate insulating layer 22 may include silicon oxide, silicon nitride, silicon oxynitride, low-k dielectric, high-k dielectric, or a combination thereof.

A channel structure 25 may be disposed on the side surface of the first gate insulating layer 22. The channel structure 25 may include monocrystalline silicon, polysilicon, doped polysilicon, or a combination thereof. A source region, a channel region and a drain region may be formed in the channel structure 25. In an embodiment, the channel region may be formed between the source region and the drain region in the vertical direction.

A third insulating pattern 26, a second gate insulating layer 27, a word line WL and a fourth insulating pattern 29 may be formed on a side surface of the channel structure 25. The second gate insulating layer 27 may electrically insulate the word line WL and the channel structure 25 from each other.

The third insulating pattern 26, the second gate insulating layer 27 and the fourth insulating pattern 29 may include silicon oxide, silicon nitride, silicon oxynitride, low-k dielectric, high-k dielectric, or a combination thereof. The word line WL may include a conductive material such as metal, metal oxide, metal nitride, metal silicide, polysilicon, conductive carbon or a combination thereof.

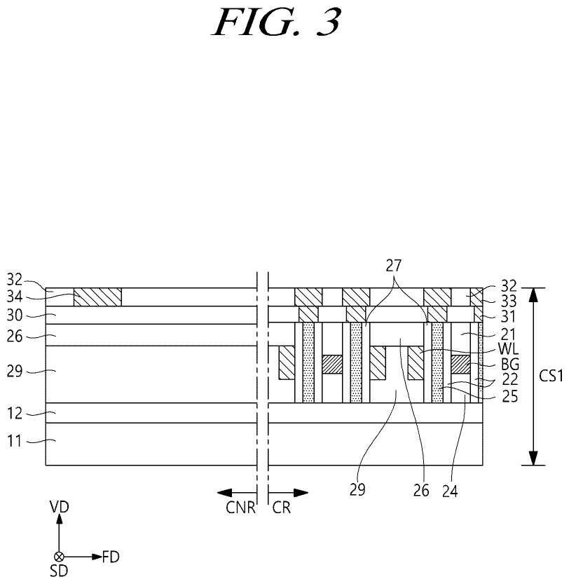

Referring to FIG. 3, a first interlayer insulating layer 30 may be formed on the first insulating pattern 21, the third insulating pattern 26, the first gate insulating layer 22, the second gate insulating layer 27 and the channel structure 25. A storage node contact 31 may be formed in the first interlayer insulating layer 30. The storage node contact 31 may be connected to a corresponding channel structure 25.

A second interlayer insulating layer 32 may be formed on the first interlayer insulating layer 30 and the storage node contact 31. A landing pad 33 may be formed in the second interlayer insulating layer 32 in a cell region CR. The landing pad 33 may be connected to a corresponding storage node contact 31. In a connection region CNR, a conductive pad 34 may be formed in the second interlayer insulating layer 32. The upper surface of the conductive pad 34 may be arranged on substantially the same plane as the upper surface of the landing pad 33.

The first interlayer insulating layer 30 and the second interlayer insulating layer 32 may include silicon oxide, silicon nitride, silicon oxynitride, low-k dielectric, high-k dielectric, or a combination thereof. The storage node contact 31, the landing pad 33 and the conductive pad 34 may include a conductive material such as metal, metal oxide, metal nitride, metal silicide, polysilicon, conductive carbon or a combination thereof.

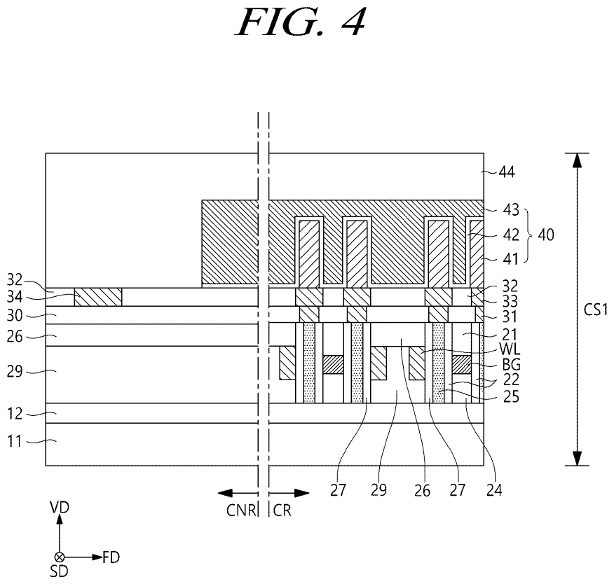

Referring to FIG. 4, a data storage pattern 40 may be formed on the second interlayer insulating layer 32 and the landing pad 33. In an embodiment, the data storage pattern 40 may be a capacitor. A first electrode 41 of the data storage pattern 40 may be formed to be connected to a corresponding landing pad 33. In some embodiments, support layers for supporting the first electrode 41 may be further formed on a side surface of the first electrode 41. A dielectric layer 42 may be formed on the surface of the first electrode 41. The dielectric layer 42 may also be formed partially in the connection region CNR. A second electrode 43 may be formed on the dielectric layer 42. The second electrode 43 may cover the entire upper surface of the dielectric layer 42. A first insulating layer 44 may be formed on the second electrode 43.

The first electrode 41 and the second electrode 43 may include a conductive material such as metal, metal oxide, metal nitride, metal silicide, polysilicon, conductive carbon or a combination thereof. The dielectric layer 42 may include high-k dielectric such as hafnium oxide, zirconium oxide or a combination thereof. The first insulating layer 44 may include silicon oxide, silicon nitride, silicon oxynitride, low-k dielectric, high-k dielectric, or a combination thereof.

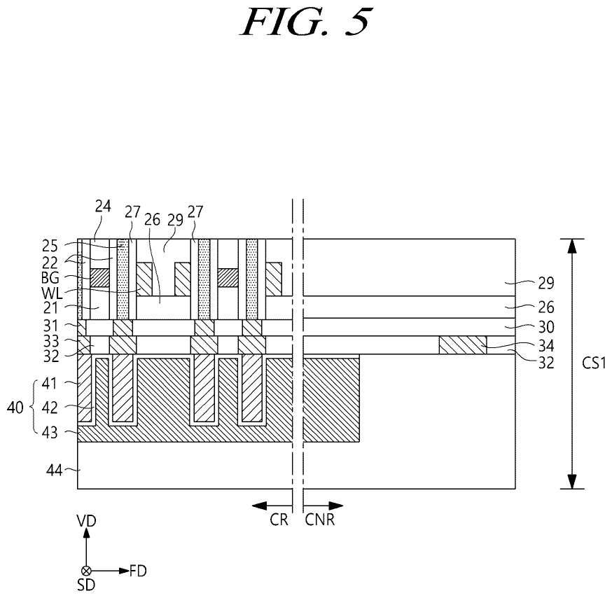

Referring to FIG. 5, the second substrate 11 and the fifth insulating layer 12 of FIG. 4 may be removed. In an embodiment, a process of removing the second substrate 11 may include a laser lift-off (LLO) process. In an embodiment, a process of removing the fifth insulating layer 12 may include an etching process.

When the second substrate 11 and the fifth insulating layer 12 are removed, the upper surfaces of the second insulating pattern 24, the first gate insulating layer 22, the second gate insulating layer 27, the fourth insulating pattern 29 and the channel structure 25 may be exposed.

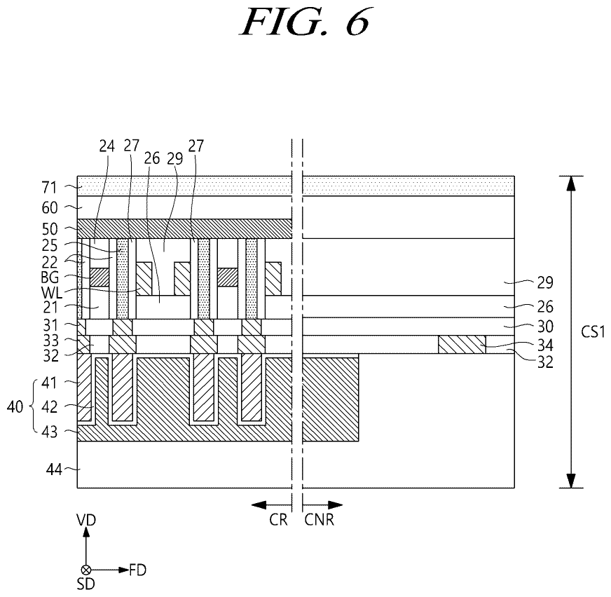

Referring to FIG. 6, in the cell region CR, a bit line 50 may be formed on the upper surfaces of the second insulating pattern 24, the first gate insulating layer 22, the second gate insulating layer 27, the fourth insulating pattern 29 and the channel structure 25. The bit line 50 may contact the upper surface of the channel structure 25. The bit line 50 may include a conductive material such as metal, metal oxide, metal nitride, metal silicide, polysilicon, conductive carbon or a combination thereof.

A second insulating layer 60 may be disposed on the bit line 50. The second insulating layer 60 may include silicon oxide, silicon nitride, silicon oxynitride, low-k dielectric, high-k dielectric, or a combination thereof. The upper surface of the second insulating layer 60 may be planarized through a chemical mechanical polishing (CMP) process.

A first bonding insulating layer 71 may be formed on the second insulating layer 60. The first bonding insulating layer 71 may include silicon nitride, silicon oxynitride, silicon carbon nitride, or a combination thereof.

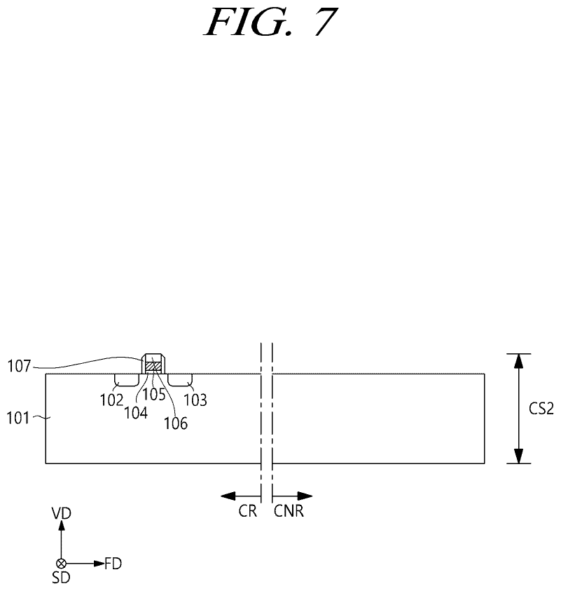

Referring to FIG. 7, a second semiconductor structure CS2 including a first substrate 101 is prepared. The first substrate 101 may include a semiconductor substrate such as a silicon wafer or a silicon-on-insulator (SOI) wafer. The first substrate 101 may include a III-V group semiconductor substrate, for example, a compound semiconductor substrate such as GaAs. The first substrate 101 may include monocrystalline silicon, polysilicon, amorphous silicon, monocrystalline silicon germanium, polycrystalline silicon germanium, carbon-doped silicon, or a combination thereof.

A source region 102, a drain region 103, a third gate insulating layer 104, a first gate electrode 105, a gate capping layer 106 and a spacer 107 may be formed in and on the first substrate 101. The source region 102 and the drain region 103 may be formed in the first substrate 101. In an embodiment, the source region 102 and the drain region 103 may be regions that are doped with an N-type impurity such as phosphorus (P), arsenic (As) or a combination thereof. The third gate insulating layer 104, the gate capping layer 106 and the spacer 107 may include silicon oxide, silicon nitride, silicon oxynitride, low-k dielectric, high-k dielectric, or a combination thereof. The first gate electrode 105 may include a conductive material such as metal, metal oxide, metal nitride, metal silicide, polysilicon, conductive carbon or a combination thereof.

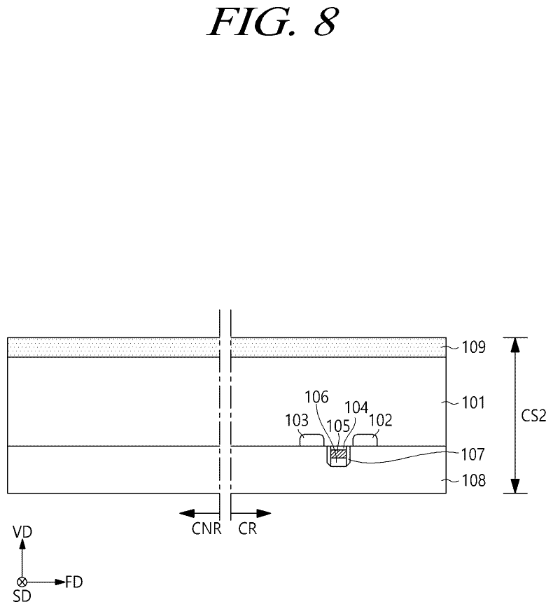

Referring to FIG. 7 and FIG. 8, a third insulating layer 108 may be formed on one surface (e.g., the upper surface) of the first substrate 101. The third insulating layer 108 may cover the source region 102, the drain region 103, the spacer 107 and the gate capping layer 106. The third insulating layer 108 may include silicon oxide, silicon nitride, silicon oxynitride, low-k dielectric, high-k dielectric, or a combination thereof.

A second bonding insulating layer 109 may be formed on the other surface (e.g., the lower surface) of the first substrate 101. The second bonding insulating layer 109 may be formed opposite to the third insulating layer 108 when viewed on the basis of the first substrate 101. In an embodiment, before forming the second bonding insulating layer 109, a process of removing a portion of the first substrate 101 may be performed. The process of removing a portion of the first substrate 101 may include a process of polishing the other surface (e.g., the lower surface) of the first substrate 101 through a chemical mechanical polishing process. The second bonding insulating layer 109 may include silicon nitride, silicon oxynitride, silicon carbon nitride, or a combination thereof.

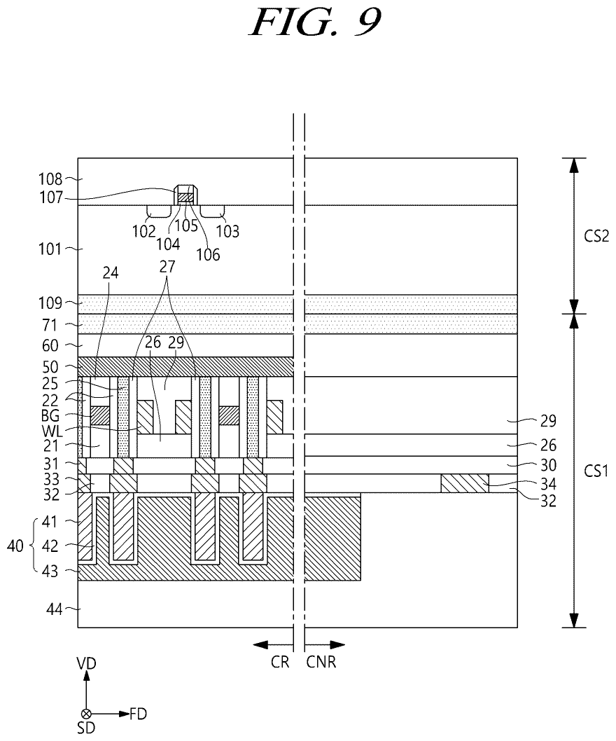

Referring to FIG. 9, the second semiconductor structure CS2 may be bonded onto the first semiconductor structure CS1. In an embodiment, the second semiconductor structure CS2 may be bonded to the first semiconductor structure CS1 through a fusion bonding process. For example, bonding the second semiconductor structure CS2 to the first semiconductor structure CS1 may include a process of bonding the second bonding insulating layer 109 to the first bonding insulating layer 71. One surface of the second bonding insulating layer 109 may contact one surface of the first bonding insulating layer 71. After the second bonding insulating layer 109 and the first bonding insulating layer 71 come into contact with each other, heat may be applied.

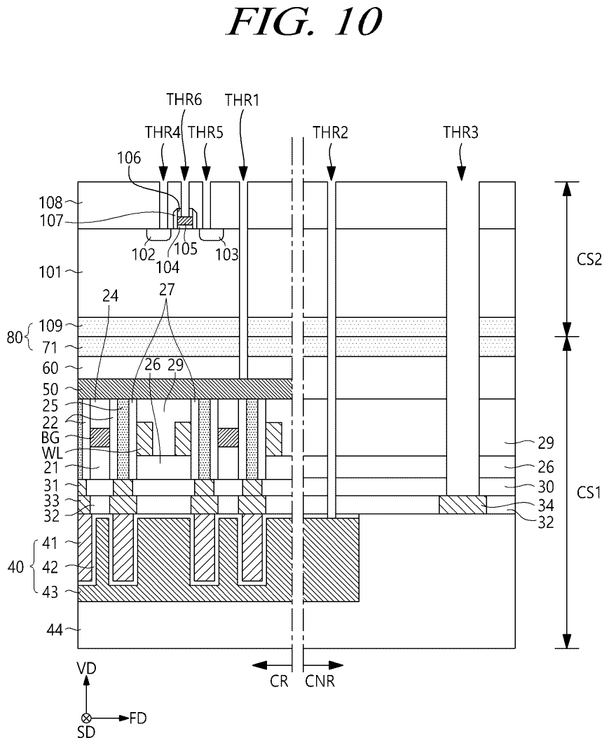

Referring to FIG. 10, through holes THR1, THR2, THR3, THR4, THR5 and THR6 may be formed in the first semiconductor structure CS1 and the second semiconductor structure CS2. In FIG. 10, six through holes THR1, THR2, THR3, THR4, THR5 and THR6 are illustrated, but this is for an illustration purpose only and the number of through holes included in a semiconductor device is not limited thereto.

The through holes THR1, THR2, THR3, THR4, THR5 and THR6 may be formed at the same manufacturing stage. A process of forming the through holes THR1, THR2, THR3, THR4, THR5 and THR6 may include an etching process.

The first through hole THR1 may expose the upper surface of the bit line 50 by penetrating through the third insulating layer 108, the first substrate 101, a bonding insulating layer 80 and the second insulating layer 60. In some embodiments, the first through hole THR1 may be formed in the connection region CNR as well as in the cell region CR.

The second through hole THR2 may expose the second electrode 43 by penetrating the third insulating layer 108, the first substrate 101, the bonding insulating layer 80, the second insulating layer 60, the fourth insulating pattern 29, the third insulating pattern 26, the first interlayer insulating layer 30, the second interlayer insulating layer 32 and the dielectric layer 42. In some embodiments, a lower end of the second through hole THR2 may penetrate a portion of the second electrode 43 and be located lower than the uppermost surface of the second electrode 43.

The third through hole THR3 may expose the upper surface of the conductive pad 34 by penetrating through the third insulating layer 108, the first substrate 101, the bonding insulating layer 80, the second insulating layer 60, the fourth insulating pattern 29, the third insulating pattern 26 and the first interlayer insulating layer 30. In an embodiment, the width of the third through hole THR3 may be larger than the width of the first through hole THR1 and the width of the second through hole THR2.

The fourth through hole THR4 and the fifth through hole THR5 may expose the upper surfaces of the source region 102 and the drain region 103, respectively, by penetrating through the third insulating layer 108. The sixth through hole THR6 may expose the upper surface of the first gate electrode 105 by penetrating through the third insulating layer 108 and the gate capping layer 106.

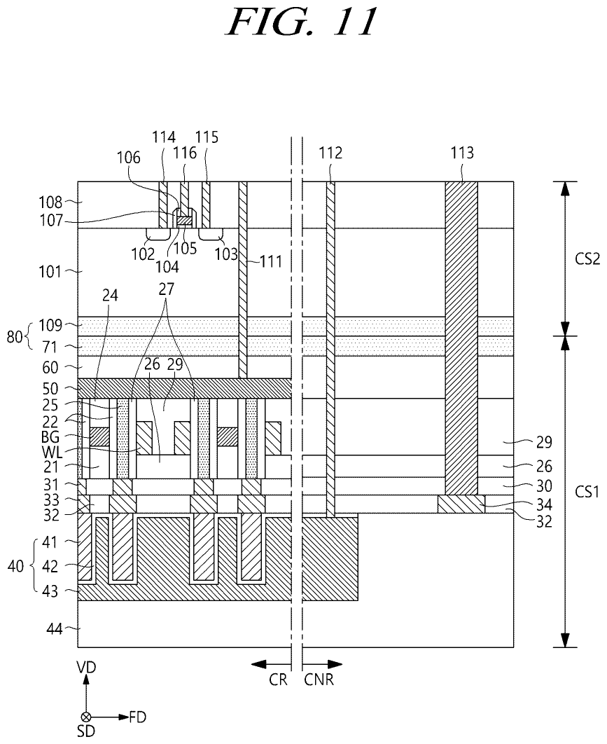

Referring to FIG. 10 and FIG. 11, a conductive material fills in the through holes THR1, THR2, THR3, THR4, THR5 and THR6 to form a first contact plug 111, a second contact plug 112, a third contact plug 113, a source contact 114, a drain contact 115 and a gate contact 116, respectively.

The lower surface of the first contact plug 111 may contact the upper surface of the bit line 50. The lower surface of the second contact plug 112 may contact the upper surface of the second electrode 43. The lower surface of the third contact plug 113 may contact the upper surface of the conductive pad 34. The lower surfaces of the source contact 114 and the drain contact 115 may contact the upper surfaces of the source region 102 and the drain region 103, respectively. The lower surface of the gate contact 116 may contact the upper surface of the first gate electrode 105.

The upper surface of the first contact plug 111, the upper surface of the second contact plug 112, the upper surface of the third contact plug 113, the upper surface of the source contact 114, the upper surface of the drain contact 115 and the upper surface of the gate contact 116 may be arranged on substantially the same plane.

The first contact plug 111, the second contact plug 112, the third contact plug 113, the source contact 114, the drain contact 115 and the gate contact 116 may include a conductive material such as metal, metal oxide, metal nitride, metal silicide, polysilicon, conductive carbon or a combination thereof. In an embodiment, the first contact plug 111, the second contact plug 112, the source contact 114, the drain contact 115 and the gate contact 116 may include tungsten (W), tungsten nitride, or a combination thereof. In an embodiment, the third contact plug 113 may include copper (Cu), tantalum (Ta), tantalum nitride, or a combination thereof.

Referring again to FIG. 1, a fourth insulating layer 117 is formed on the first contact plug 111, the second contact plug 112, the third contact plug 113, the source contact 114, the drain contact 115 and the gate contact 116. The fourth insulating layer 117 may include silicon oxide, silicon nitride, silicon oxynitride, low-k dielectric, high-k dielectric, or a combination thereof.

A first wiring 121, a second wiring 122, a third wiring 123, a source wiring 124 and a gate wiring 125 may be formed in the fourth insulating layer 117. The first wiring 121 may be connected to the first contact plug 111 and the drain contact 115. The second wiring 122 may be connected to the second contact plug 112. The third wiring 123 may be connected to the third contact plug 113. The source wiring 124 may be connected to the source contact 114. The gate wiring 125 may be connected to the gate contact 116.

The first wiring 121, the second wiring 122, the third wiring 123, the source wiring 124 and the gate wiring 125 may be spaced apart from each other. The upper surface of the first wiring 121, the upper surface of the second wiring 122, the upper surface of the third wiring 123, the upper surface of the source wiring 124 and the upper surface of the gate wiring 125 may be located on substantially the same plane.

According to embodiments of the present disclosure, the second semiconductor structure CS2 including the first transistor TR1 may be bonded onto the first semiconductor structure CS1 including the memory cells. The first transistor TR1 may be disposed on the second surface 101b of the first substrate 101.

Because the first transistor TR1 is disposed at the upper part of the semiconductor device, the outside of the semiconductor device and the first transistor TR1 may be easily connected. For example, the distance between an external device located on the semiconductor device and the first transistor TR1 in the vertical direction may be smaller than the distance between the external device and the first transistor TR1 when the first transistor TR1 is disposed in the lower part of the first semiconductor structure CS1. Accordingly, when the first transistor TR1 is disposed at the upper part of the semiconductor device, the number of wirings or contacts required to connect the outside of the semiconductor device and the first transistor TR1 may be reduced, and the lengths of the contacts for connecting the wirings may be reduced. Therefore, a process of forming wirings included in the semiconductor device may be simplified.

The above description has been presented to enable any person skilled in the art to make, use and practice the technical features of the present disclosure, and has been provided in the context of a particular application and its requirements as examples. Various modifications, additions and substitutions to the described embodiments will be readily apparent to those skilled in the art, and the principles described herein may be applied to other embodiments and applications without departing from the scope of the present disclosure. Therefore, the embodiments disclosed above and in the accompanying drawings should be considered in a descriptive sense only and not for limiting the technological scope. The technological scope of the present disclosure is not limited by the embodiments and the accompanying drawings.

What is claimed is:

1. A memory device comprising:
a channel structure including a first end and a second end that is opposite to the first end in a vertical direction;
a data storage pattern connected to the first end of the channel structure;
a bit line contacting the second end of the channel structure;
a bonding insulating layer disposed over the bit line;
a first substrate disposed over the bonding insulating layer, and including a first surface that faces the bit line and a second surface that is opposite to the first surface in the vertical direction; and
a first transistor disposed on the second surface of the first substrate.

2. The memory device according to claim 1, further comprising:
a plurality of wirings located over the first substrate, including a first wiring, a second wiring and a third wiring that are spaced apart from each other in the same layer; and
a first contact plug connecting the first wiring and the bit line by penetrating through the first substrate and the bonding insulating layer.

3. The memory device according to claim 2, wherein the first transistor is located in the vertical direction between at least one of the plurality of wirings and the first surface of the first substrate.

4. The memory device according to claim 2, wherein the first transistor is connected to the first wiring.

5. The memory device according to claim 2, further comprising
a second contact plug penetrating through the first substrate and the bonding insulating layer to connect the second wiring and the data storage pattern.

6. The memory device according to claim 5, wherein the data storage pattern comprises:
a first electrode;
a second electrode surrounding the first electrode; and
a dielectric layer between the first electrode and the second electrode,
wherein the second contact plug is connected to the second electrode.

7. The memory device according to claim 2, further comprising
a through electrode penetrating through the first substrate and the bonding insulating layer, and connected to the third wiring.

8. The memory device according to claim 7, further comprising:
a landing pad disposed between the data storage pattern and the channel structure; and
a conductive pad disposed at the same layer as the landing pad,
wherein the through electrode is connected to the conductive pad.

9. A memory device comprising:
a first semiconductor structure including a channel structure, a bit line that contacts an upper surface of the channel structure and a first bonding insulating layer over the bit line;
a second semiconductor structure including a second bonding insulating layer that is bonded to the first bonding insulating layer, a first substrate that is disposed over the second bonding insulating layer and a first transistor that is disposed on the first substrate; and
a plurality of contact plugs, including a first contact plug, a second contact plug and a third contact plug that are spaced apart from each other, that connect the first semiconductor structure and the second semiconductor structure by penetrating through the first substrate, the first bonding insulating layer and the second bonding insulating layer.

10. The memory device according to claim 9, wherein
the second semiconductor structure further includes a plurality of wirings that are located over the first substrate, and
each of the plurality of contact plugs is connected to one of the plurality of wirings.

11. The memory device according to claim 10, wherein the first transistor is arranged between at least one of the plurality of wirings and the second bonding insulating layer.

12. The memory device according to claim 10, wherein
the plurality of wirings includes a first wiring, a second wiring and a third wiring that are spaced apart from each other in the same layer, and
the first contact plug connects the first wiring and the bit line.

13. The memory device according to claim 12, wherein the first transistor is connected to the first wiring.

14. The memory device according to claim 10, wherein
the first semiconductor structure further includes a data storage pattern that is connected to a lower surface of the channel structure,
the plurality of wirings includes a first wiring, a second wiring and a third wiring that are spaced apart from each other in the same layer, and
the second contact plug connects the second wiring and the data storage pattern.

15. The memory device according to claim 14, wherein the data storage pattern comprises:
a first electrode;
a second electrode surrounding the first electrode; and
a dielectric layer between the first electrode and the second electrode,
wherein the second contact plug is connected to the second electrode.

16. The memory device according to claim 10, wherein
the plurality of wirings includes a first wiring, a second wiring and a third wiring that are spaced apart from each other in the same layer, and
the third contact plug is connected to the third wiring.

17. The memory device according to claim 16, wherein the first semiconductor structure further includes:
a landing pad connected to a lower surface of the channel structure; and
a conductive pad disposed at the same layer as the landing pad,
wherein the third contact plug is connected to the conductive pad.

18. A memory device comprising:
a channel structure including a first end and a second end that is located opposite to the first end in a vertical direction;
a data storage pattern connected to the first end of the channel structure;
a bit line contacting the second end of the channel structure;
a bonding insulating layer located over the bit line;
a first substrate located over the bonding insulating layer;
a plurality of wirings located over the first substrate; and
a plurality of contact plugs directly connected to the plurality of wirings, respectively, and penetrating through the bonding insulating layer and the first substrate.

19. The memory device according to claim 18, further comprising
a first transistor disposed on the first substrate,
wherein the first transistor is connected to at least one of the plurality of wirings.

20. The memory device according to claim 18, wherein at least one of the plurality of contact plugs connects any one of the plurality of wirings and the bit line.
